(19) United States
(12) Patent Application Publication
(10) Pub. No.: US 2022/0360070 A1
(43) Pub. Date: Nov. 10, 2022

(54) PROTECTION APPARATUS FOR A DRIVER CIRCUIT, AND METHOD FOR PROTECTING A DRIVER CIRCUIT

(71) Applicant: Robert Bosch GmbH, Stuttgart (DE)

(72) Inventor: Tim Bruckhaus, Asperg (DE)

(21) Appl. No.: 17/599,124

(22) PCT Filed: Mar. 18, 2020
(86) PCT No.: PCT/EP2020/057374

§ 371 Date: Sep. 28, 2021

(30) Foreign Application Priority Data
Mar. 29, 2019 (DE) 10 2019 204 429.8

(51) Int. Cl. H02H 3/24

(52) U.S. Cl. CPC H02H 3/24

(57) ABSTRACT

The present invention relates to the protection of a driver circuit for actuating a semiconductor switch. A voltage drop in a series resistor between the driver circuit and a control connection of the semiconductor switch is evaluated for this purpose. If the voltage drop across the series resistor exceeds a prespecified threshold value and this threshold value is exceeded for at least a predetermined period of time, the driver circuit for the semiconductor switch is then deactivated.

### BACKGROUND OF THE INVENTION

The present invention relates to a protection apparatus for a driver circuit for actuating a semiconductor switch and to a method for protecting a driver circuit for actuating a semiconductor switch. The present invention further relates to a control apparatus for a semiconductor switch and to an inverter arrangement.

Electric drive systems, as are used for example in fully or partly electrically driven vehicles, generally comprise an electric machine, which is fed by a converter. In this case, the converter generally comprises a plurality of half-bridges with power semiconductor switches. These power semiconductor switches are actuated by way of a driver circuit, which amplifies the control signals in order to provide a sufficient electrical power for actuating the power semiconductor switches.

Document DE 10 2015 217 175 A1 discloses an actuation circuit for an inverter of a vehicle. The inverter is designed to convert a DC voltage from an electrical energy store to an alternating current with which an electric machine of a vehicle is operated. The actuation circuit comprises a driver unit, which generates inverter control signals for the switching elements of the inverter.

In the event of a fault in a power semiconductor switch, a short circuit may arise between the control terminal of the power semiconductor switch and a further output of the power semiconductor switch. An output of a driver stage for the actuation of the power semiconductor switch can be subjected to high load due to such a short circuit.

### SUMMARY OF THE INVENTION

The present invention discloses a protection apparatus for a driver circuit for actuating a semiconductor switch, and also a method for protecting a driver circuit for actuating a semiconductor switch having the features of the independent patent claims. Further advantageous embodiments are the subject matter of the dependent patent claims.

The following is provided accordingly:

A protection apparatus for a driver circuit for actuating a semiconductor switch. The driver circuit is electrically coupled to a control terminal of the semiconductor switch by means of an electrical series resistor. The protection apparatus is designed to ascertain a voltage drop across the series resistor of the driver circuit. The protection apparatus is further designed to deactivate the driver circuit when a predetermined characteristic has been detected in the detected voltage drop. In particular, the driver circuit can be deactivated when the detected voltage drop exceeds a predetermined value for at least a prescribed period of time.

The following is furthermore provided:

A method for protecting a driver circuit for actuating a semiconductor switch, wherein the driver circuit is electrically coupled to the control terminal of the semiconductor switch by means of an electrical series resistor. The method comprises a step of ascertaining a voltage drop across the series resistor of the driver circuit and a step of deactivating the driver circuits when a predetermined characteristic has been detected in the detected voltage drop. In particular, the driver circuit is deactivated when the detected voltage drop exceeds a predetermined threshold value for at least a prescribed period of time.

The present invention is based on the knowledge that, in the event of a fault, in particular in the case of failure, of a power semiconductor switch, a short circuit may arise between the control terminal and a further terminal of the power semiconductor switch. In the case of such a short circuit, a driver circuit, which feeds the control input of the power semiconductor switch, can be subjected to very high load, that is to say a relatively high electric current can flow. This high loading of the output of the driver circuit can possibly lead to further damage within the driver stage or else further components. This results in the risk of a fault in a power semiconductor switch leading to further damage in the driver circuit.

It is therefore an idea of the present invention to take this knowledge into consideration and to provide protection for a driver circuit of a semiconductor switch, which makes it possible to reliably disconnect the driver stage having the faulty semiconductor switch in the event of a fault. In this way, it is possible to prevent further damage within the driver stage. Moreover, by disconnecting the driver stage of a faulty semiconductor switch in as timely a manner as possible, it is possible to prevent the fault from spreading into further components, for example into further driver stages or similar.

If a faulty power semiconductor switch is identified early and subsequently the affected driver stage for this semiconductor switch is deactivated, it is thus possible, where necessary, to prevent the fault from spreading into further components. This makes it possible for example for an electrical system to pass into a safe operating state, for example an active short circuit or similar, in the event of a fault. The safety of an electrical drive system can be increased in this way.

Moreover, the deactivation of the driver circuit in the case of a fault in the connected semiconductor switch can be used to prevent damage to further components. The number of damaged components in the event of a fault can thus be reduced. This makes rapid and cost-effective repair possible.

In accordance with one embodiment, the protection apparatus comprises a low-pass filter. The low-pass filter is designed to filter the detected voltage drop across the series resistor. In particular, the low-pass filter can be designed to filter higher-frequency components in the detected voltage drop. The conventional switching operations during the actuation of the semiconductor switch generally lead to short, higher-frequency switching pulses. Suitable low-pass filtering can eliminate or at least minimize these switching pulses, with the result that, on account of the conventional switching pulses during operation, the voltage drops across the series resistor do not have a significant influence on the signal that is to be evaluated.

In accordance with one embodiment, the protection apparatus comprises a comparison device. The comparison device is designed to compare a value of the detected voltage drop across the series resistor with a predetermined threshold value. If the detected voltage drop across the series resistor, in particular the smoothed or low-pass-filtered voltage drop across the series resistor, exceeds a prescribed threshold value, this can be taken as an indication that the output of the driver circuit for the semiconductor switch is subjected to high load over a longer period of time. This generally occurs only in the event of a fault.

In accordance with one embodiment, the predetermined threshold value of the comparison device can be adjusted. In particular, it is possible for the predetermined threshold value of the comparison device to be able to be adjusted depending on a supply voltage of the driver circuit. If the driver circuit is supplied by more than one voltage, the threshold value can be adjusted depending on at least one of the plurality of supply voltages. By adjusting the threshold values for the detection of a fault, it is also possible to take into account fluctuations in the boundary conditions, such as for example a fluctuating supply voltage or similar. Fluctuations in the supply voltage of the driver circuit can thus for example also lead to higher or low voltage drops across the series resistor occurring even in normal, fault-free operation. By suitably adjusting the detection thresholds, it is possible to take into account and compensate for such effects.

In accordance with one embodiment, the protection apparatus comprises a storage device. The storage device is designed to pass from a first state to a second state when the comparison device has detected an exceedance of the voltage drop beyond the predetermined threshold value. In particular, the storage device can also maintain the second state when the voltage drop across the series resistor falls below the predetermined threshold value again. Permanent disconnection of the driver circuit after the detection of a fault can be ensured in this way. For example, the storage device may be a bistable multivibrator, such as for example a flip-flop or similar. Where necessary, the storage device can be reset, that is to say passed to the first state, by applying a suitable reset signal. When the storage device is in the first state, the driver circuit for actuating the semiconductor switch can be activated.

Furthermore, a control apparatus for a semiconductor switch having a driver circuit and a protection apparatus according to the invention is provided. The driver circuit is designed to provide a control signal at a control input of the semiconductor switch.

An inverter arrangement having a plurality of semiconductor switches and a control apparatus as described above is also provided, wherein each driver circuit is designed to actuate at least one of the plurality of semiconductor switches.

In accordance with one embodiment of the inverter arrangement, a separate control device is provided for each semiconductor switch of the plurality of semiconductor switches.

The above configurations and developments can be combined with one another as desired, where appropriate. Further configurations, developments and implementations of the invention also comprise combinations that are not explicitly mentioned of features of the invention that are described above or below with respect to the exemplary embodiments. In particular, a person skilled in the art will also add individual aspects as improvements or additions to the respective basic forms of the invention.

### BRIEF DESCRIPTION OF THE DRAWINGS

Further features and advantages of the present invention are explained below with reference to the figures, in which:

FIG. 1: shows a schematic illustration of a control apparatus for a semiconductor switch having a protection apparatus in accordance with one embodiment;

FIG. 2: shows a schematic illustration of a control apparatus for a semiconductor switch having a protection apparatus in accordance with a further embodiment;

FIG. 3: shows a schematic illustration of an inverter arrangement in accordance with one embodiment; and

FIG. 4: shows a flowchart based on a method for protecting a driver circuit in accordance with one embodiment.

### DETAILED DESCRIPTION

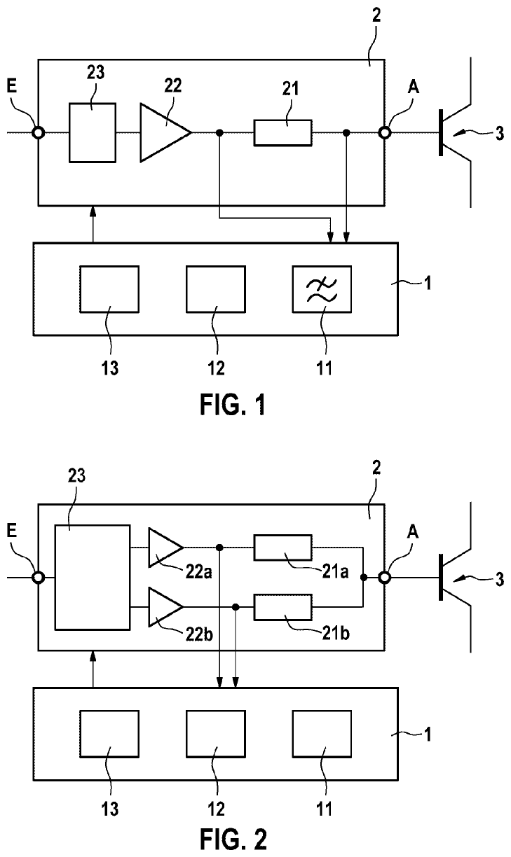

FIG. 1 shows a schematic illustration of a block circuit diagram of a control apparatus for actuating a semiconductor switch 3 in accordance with one embodiment. The control apparatus for actuating the semiconductor switch 3 comprises a driver circuit 2 and a protection apparatus 1 for the driver circuit 2. A control signal, which is prepared by the driver circuit 2, can be provided at an input E of the driver circuit 2 in order to provide an actuation signal, which has a sufficient voltage level and power to drive a control terminal of the semiconductor switch 3, at the output A of the driver circuit 2. To this end, the input signal of the driver circuit 2 can be received and prepared by a circuit 23, for example a gate driver IC or similar. The signal can subsequently be amplified by an amplifier circuit 22 and provided at the output A by way of a series resistor 21. The output A of the driver circuit 2 is electrically coupled to the control terminal of the semiconductor switch 3, with the result that the signal provided at the output A can actuate the semiconductor switch 3.

During the actuation of the semiconductor switch 3, a current flows for a relatively short period of time from the output A of the driver circuit 2 to the control terminal of the semiconductor switch 3.

If a fault arises in the semiconductor switch 3, a short circuit can also arise between the control terminal of the semiconductor switch 3 and a further terminal of the semiconductor switch 3. This short circuit can lead to a greater current being able to flow for a longer period of time from the output terminal A of the driver circuit 2 in the direction of the semiconductor switch 3. This high flow of current in this case also leads to a corresponding voltage drop across the series resistor 21.

The protection apparatus 1 for the driver circuit 2 is coupled to the driver circuit 2 in such a way that the protection apparatus 1 can detect a voltage drop across the series resistor 21. While normal switching operations for the control terminal of the semiconductor switch 3 lead only to relatively short current pulses and associated short voltage drops across the series resistor 21, a fault in the semiconductor switch 3 leads to a longer flow of current and in association also to a voltage drop across the series resistor 21 that lasts for a longer time. Such a voltage drop that lasts for longer than a prescribed period of time can be identified by the protection apparatus 1. The protection apparatus 1 can subsequently deactivate the driver circuit 2. For example, the protection apparatus 1 can provide at the driver circuit 2 a control signal that activates or deactivates the driver circuit 2. For example, the driver circuit 2 can be activated only as long as an active enable signal is applied by the protection apparatus 1. If this active enable signal is switched off, the driver circuit 2 is subsequently also deactivated. The reverse, that the protection apparatus 1 outputs an active signal to deactivate the driver circuit 2, is of course also possible.

As already stated above, the normal control pulses for actuating the semiconductor switch 3 during normal operation cause only relatively brief voltage drops across the series resistor 21. In contrast, in the event of a fault, a voltage drop across the series resistor 21 can be detected for a longer period of time. In order to distinguish between these two states, a low-pass filter 11, which filters a signal corresponding to the voltage drop across the series resistor 21, can be provided in the protection apparatus 1 for the driver circuit 2. In this way, higher-frequency signal components can be eliminated or at least minimized, with the result that only the low-frequency component of the voltage drop across the series resistor 21 is evaluated for the further evaluation. Any desired low-pass filter, for example an R-C element or similar, can be used for the low-pass filtering.

The signal prepared accordingly can subsequently be fed to a comparison device 12, which compares the detected voltage drop across the series resistor 21 with a prescribed threshold value. If the detected voltage drop across the series resistor 21 exceeds the prescribed threshold value, this can be taken as an indication that a fault has arisen in the semiconductor switch 3.

If necessary, the prescribed threshold value with which the comparison device 12 compares the voltage drop across the series resistor 21 can be adjusted. For example, the threshold for the comparison can be adjusted depending on a supply voltage of the driver circuit 2. A variation in the supply voltage of the driver circuit 2 can in some circumstances lead to the electric currents from the driver circuit 2 to the control terminal of the semiconductor switch 3 also changing depending on the level of the supply voltage. By (dynamically) adjusting the detection threshold in the comparison device 12, it is possible to take into account and, if necessary, compensate for such effects.

An output of the comparison device 12 can be coupled to a storage device 13. The storage device 13 can change for example from a first state to a second state when the comparison device 12 detects an exceedance of the voltage drop across the series resistor 21 beyond the prescribed threshold value. Moreover, the storage device 13 can also remain in the second state even if the voltage drop across the series resistor 21 falls to below the prescribed threshold value again. In this way, the storage device 13 can detect a fault case and provide a disconnection signal for the deactivation of the driver circuit 2 after detection of a fault, that is to say an exceedance of the voltage drop across the series resistor 21 for a prescribed period of time. This disconnection signal is to be maintained permanently after the detection of a fault. For example, a flip-flop or similar can be used for this purpose. If necessary, the storage device 13 can be reset by means of a reset signal.

FIG. 2 shows a schematic illustration of a block circuit diagram of a control apparatus for a semiconductor switch 3 in accordance with a further embodiment. The control apparatus in accordance with FIG. 2 differs from the control apparatus described above in particular in that the driver IC 23 of the driver circuit 2 splits the control signal into two signals. The corresponding signal paths are denoted by the letters a and b. To close the semiconductor switch 3, the top path a can carry a positive output current, for example. In this case, the path b then has a high impedance. To open the semiconductor switch 3, the bottom path b can carry a negative output current. In this case, the path a then has a high impedance. In this way, separate control signals are generated for opening and closing the semiconductor switch 3. Moreover, the control apparatus for actuating the semiconductor switch 3 and in particular the protection apparatus 1 corresponds to the embodiment described above in accordance with FIG. 1.

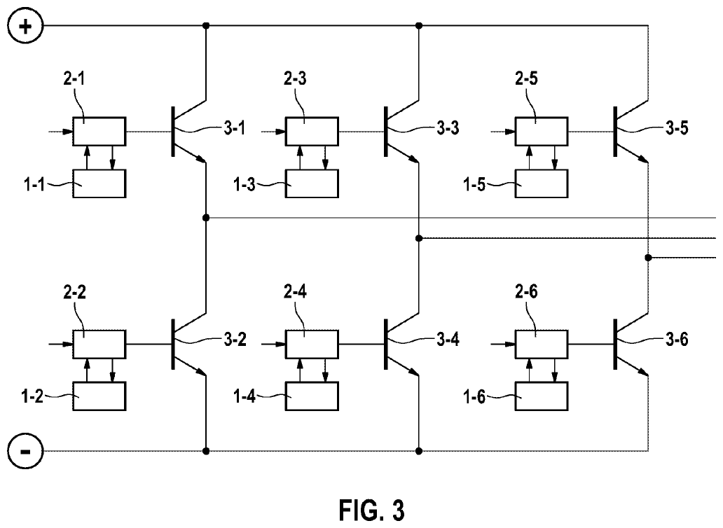

FIG. 3 shows a schematic illustration of an inverter arrangement in accordance with one embodiment. The inverter arrangement can comprise for example three half-bridges each having two semiconductor switches 3. Each of these semiconductor switches 3 can be actuated by a driver circuit 2. Moreover, a protection apparatus 1 in accordance with one of the embodiments described above can be provided for each driver circuit 2. Individual protection for the driver circuits 2 of the semiconductor switches 3 can be provided in this way. In particular, when a fault, in particular a short circuit between the control terminal and a further terminal, arises in one of the semiconductor switches 3, the corresponding driver circuit 2 can be deactivated by the corresponding protection apparatus 1. In this case, the operation of the remaining semiconductor switches and the associated driver circuits 2 is not influenced. In particular, when the inverter circuit is provided for example for actuation of an electric machine, the inverter arrangement can be passed to a safe operating state in the event of a fault in one of the semiconductor switches 3.

For example, such a safe operating state may be an active short circuit in which all of the top or bottom semiconductor switches are closed at the same time. If for example a fault arises in one of the bottom semiconductor switches 3 and an associated short circuit arises in the corresponding semiconductor switch 3, the remaining two bottom semiconductor switches can likewise be closed. The three top semiconductor switches 3 are in this case all opened. An analogous procedure can also take place in the case of a short circuit in one of the top semiconductor switches 3. By deactivating the driver circuit of a faulty semiconductor switch 3, it is furthermore possible here to safely actuate the other semiconductor switches 3.

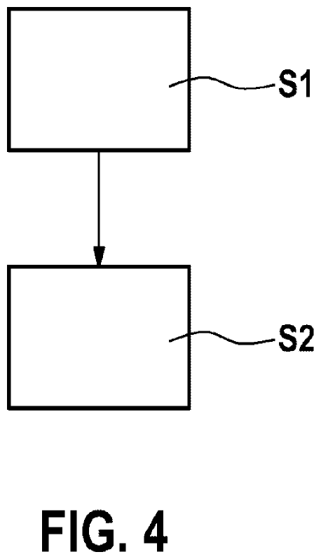

FIG. 4 shows a schematic illustration of a flowchart based on a method for protecting a driver circuit for actuating a semiconductor switch in accordance with one embodiment. The method can be applied in particular to a driver circuit 2 for actuating a semiconductor switch 3, wherein the driver circuit 2 is electrically coupled to a control terminal of the semiconductor switch 3 by means of an electrical series resistor 21. In step S1, a voltage drop across the series resistor 21 of the driver circuit 2 is ascertained. In step S2, the driver circuit 2 is deactivated when a predetermined characteristic has been detected in the detected voltage drop. As described above, the predetermined characteristic may be for example an exceedance of the voltage drop beyond a threshold value for a predetermined period of time. As described above, the voltage drop can be filtered by means of a low-pass filter and the filtered voltage drop can be compared with a threshold value for this purpose. If the detected voltage drop exceeds a prescribed threshold value and if the threshold value is exceeded for at least a prescribed period of time, the actuation of the semiconductor switch can be deactivated. This deactivation can be maintained even if the detected voltage drop falls below the prescribed threshold value again.

In summary, the present invention relates to the protection of a driver circuit for actuating a semiconductor switch. To this end, a voltage drop in a series resistor between the driver circuit and a control terminal of the semiconductor switch is evaluated. If the voltage drop across the series resistor exceeds a prescribed threshold value and if this threshold value is exceeded for at least a predetermined period of time, the driver circuit for the semiconductor switch is subsequently deactivated.

1. A protection apparatus (1) for a driver circuit (2) for actuating a semiconductor switch (3), wherein the driver circuit (2) is electrically coupled to a control terminal of the semiconductor switch (3) by means of an electrical series resistor (21),
wherein the protection apparatus (1) is configured to ascertain a voltage drop across the series resistor (21) of the driver circuit (2) and to deactivate the driver circuit (2) when a predetermined characteristic has been detected in the detected voltage drop.

2. The protection apparatus (1) as claimed in claim 1, further comprising a low-pass filter (11), which is designed to filter the detected voltage drop across the series resistor (21).

3. The protection apparatus (1) as claimed in claim 1, further comprising a comparison device (12), which is designed to compare a value of the detected voltage drop across the series resistor (21) with a predetermined threshold value.

4. The protection apparatus (1) as claimed in claim 3, further configured to adjust the predetermined threshold value.

5. The protection apparatus (1) as claimed in claim 4, further configured to wherein the predetermined threshold value can be adjusted depending on at least one supply voltage of the driver circuit (2).

6. The protection apparatus (1) as claimed in claim 3, further comprising a storage device (13), which is designed to pass from a first state to a second state when the comparison device (12) has detected an exceedance of the voltage drop beyond the predetermined threshold value.

7. A control apparatus for a semiconductor switch (3), having:
a driver circuit (2), which is designed to provide a control signal at a control input of the semiconductor switch (3), and
a protection apparatus (1) as claimed in claim 1.

8. An inverter arrangement, having:
a plurality of semiconductor switches (3-i), and
a plurality of control apparatuses, each of the plurality of control apparatuses having
a driver circuit (2), which is designed to provide a control signal at a control input of one of the plurality of semiconductor switches (3-i), and
a protection apparatus (1).

9. (canceled)

10. A method for protecting a driver circuit (2) for actuating a semiconductor switch (3), wherein the driver circuit (2) is electrically coupled to a control terminal of the semiconductor switch (3) by means of an electrical series resistor (21), wherein the method comprises the following steps:
ascertaining (S1) a voltage drop across the series resistor (21) of the driver circuit (2); and
deactivating (S2) the driver circuit (2) when a predetermined characteristic has been detected in the detected voltage drop.
